(19) United States
(12) Patent Application Publication
(10) Pub. No.: US 2026/0231371 A1
(43) Pub. Date: Aug. 6, 2026

(54) COLD PLATES WITH COMPOSITE FOAM STRUCTURES AND METHODS OF MANUFACTURING THE SAME

(71) Applicant: Toyota Motor Engineering & Manufacturing North America, Inc., Plano, TX (US)

(72) Inventors: Ercan Mehmet Dede, Ann Arbor, MI (US); Shailesh N. Joshi, Ann Arbor, MI (US)

(73) Assignee: Toyota Motor Engineering & Manufacturing North America, Inc., Plano, TX (US)

(21) Appl. No.: 19/042,079

(22) Filed: Jan. 31, 2025

(51) Int. Cl. H05K 7/20

(52) U.S. Cl. CPC H05K 7/2039

(57) ABSTRACT

A cold plate for an electronic and/or electromechanical device includes a first face panel and a second face panel spaced apart from the first face panel, and a matrix of high thermal conductivity (HTC) spheres and a matrix of low thermal conductivity (LTC) spheres disposed between inner surfaces of the first and second face panels. The matrix of HTC spheres defines a heat conducting pathway between the first and second face panels, and the matrix of LTC spheres defines a thermal insulated region between the first and second face panels.

### TECHNICAL FIELD

The present disclosure relates to cold plates, and particularly to cold plates for electronic and/or electromechanical devices.

### BACKGROUND

Electronic devices, e.g., power electronic devices such as insulated-gate bipolar transistors (IGBTs) and metal oxide semiconductor field effect transistors (MOSFETs), and electromechanical devices such as electric motors, generate significant heat fluxes that must be removed to ensure operation below their maximum operating temperatures. Cooling devices such as heat sinks and liquid-based coolers are frequently used to cool the electronic and/or electromechanical devices. Such electronic and/or electromechanical devices (or other heat generating components) are commonly attached to a cooling assembly by a thermally conductive plate called a cold plate. However, the cold plate presents a thermal impedance, and may inefficiently pass heat flux from the electronic device to the cooling assembly. Further, it may be desired to strategically route heat flux to one region while isolating another region.

The present disclosure addresses issues related to cooling of electronic and/or electromechanical devices and other issues related to electronic and/or electromechanical devices.

### SUMMARY

This section provides a general summary of the disclosure and is not a comprehensive disclosure of its full scope or all of its features.

In one form of the present disclosure, a cold plate for an electronic and/or electromechanical device includes a first face panel and a second face panel spaced apart from the first face panel, and a matrix of high thermal conductivity (HTC) spheres and a matrix of low thermal conductivity (LTC) spheres disposed between inner surfaces of the first and second face panels. The matrix of HTC spheres defines a heat conducting pathway between the first and second face panels, and the matrix of LTC spheres defines a thermal insulated region between the first and second face panels.

In another form of the present disclosure, a cold plate for an electronic and/or electromechanical device includes a first face panel and a second face panel spaced apart from the first face panel, and a matrix of HTC spheres and a matrix of LTC spheres disposed between inner surfaces of the first and second face panels. The matrix of HTC spheres defines a heat conducting pathway between the first and second face panels, and the matrix of LTC spheres defines a thermal insulated region between the first and second face panels. A heat source is in thermal communication with an outer surface of the first face panel and a heat sink in thermal communication with an outer surface of the second face panel. And the heat conducting pathway enhances heat transfer between the heat source and the heat sink, and the thermal insulated region reduces heat transfer between the heat source and a heat insulated region on the second face panel.

In still another form of the present disclosure, a cold plate for an electronic and/or electromechanical device includes a first face panel and a second face panel spaced apart from the first face panel, a polymer matrix between inner surfaces of the first and second face panels, and a matrix of HTC spheres and a matrix of LTC spheres embedded in the polymer matrix. The matrix of HTC spheres defines a heat conducting pathway between the first and second face panels, and the matrix of LTC spheres defines a thermal insulated region between the first and second face panels. A heat source is in thermal communication with an outer surface of the first face panel, and a heat sink is in thermal communication with an outer surface of the second face panel. The heat conducting pathway enhances heat transfer between the heat source and the heat sink, and the thermal insulated region reduces heat transfer between the heat source and a heat insulated region on the second face panel.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a side cross-sectional view of a cold plate according to one form of the present disclosure;

FIG. 2 shows a side cross-sectional view of a cold plate according to another form of the present disclosure;

FIG. 3 shows a side cross-sectional view of a cold plate according to still another form of the present disclosure;

FIG. 4 shows a side cross-sectional view of a cold plate according to yet another form of the present disclosure;

FIG. 5 shows a side cross-sectional view of a cold plate according to still yet another form of the present disclosure;

FIG. 6 shows a side cross-sectional view of a cold plate according to another form of the present disclosure;

FIG. 7 is a flow chart for a method of fabricating a cold plate according to the teachings of the present disclosure;

FIG. 8 is a flow chart for another method of fabricating a cold plate according to the teachings of the present disclosure; and

FIG. 9 is a flow chart for still another method of fabricating a cold plate according to the teachings of the present disclosure.

It should be noted that the figures set forth herein are intended to exemplify the general characteristics of the methods and devices among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides cold plates for electric heat generating devices such as an electronic device and/or an electromechanical device (e.g., electric motors and/or rotors for electric motors), and methods of manufacturing such cold plates. In some variations, the electronic device is a power electronic device. As used herein, the phrase “power electronic device” refers to a semiconductor device (also known as or referred to herein as a “chip”) used as a switch or rectifier in power electronics. The cold plates include predefined and enhanced heat conduction pathways between a heat source and a heat sink and predefined thermal insulated regions between the heat source and a thermal insulated region.

In some variations, cold plates disclosed herein can include a first face panel, a second face panel spaced apart from the first face panel, and a matrix of spheres disposed between inner surfaces of the first face panel and the second face panel. Also, a heat source can be adjacent to and in thermal communication with an outer surface of the first face panel and a heat sink can be adjacent to and in thermal communication with an outer surface of the second plate. During operation of an electronic and/or electromechanical to which the cold plate is attached, heat transfer is enhanced between the heat source and the heat sink. And in at least one variation, heat transfer is reduced between the heat source and a thermal insulated region.

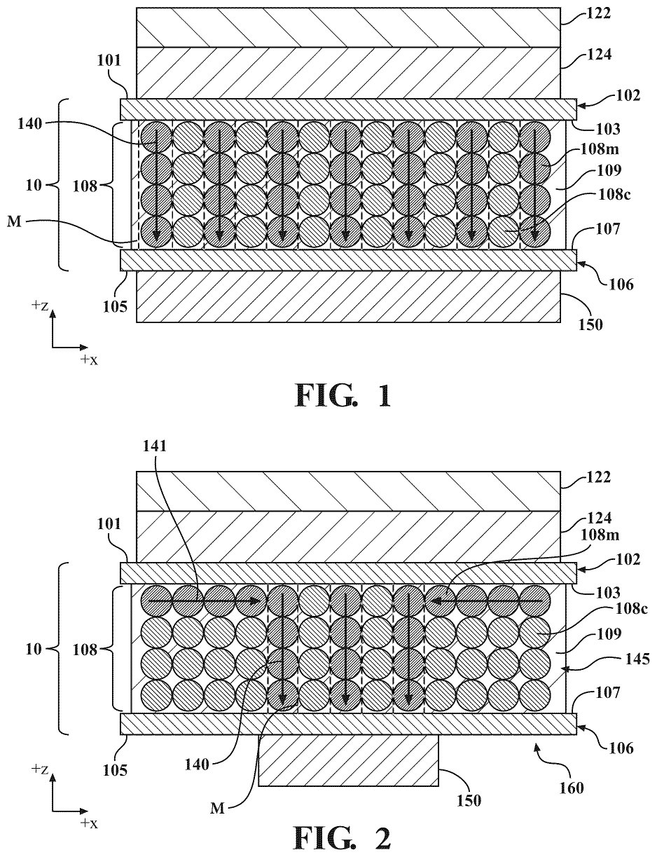

Referring to FIG. 1, a cross-sectional view of a cold plate 10 according to one form of the present disclosure is shown. As used herein, the phrase “cold plate” refers to a device that removes heat from electronic components and other surfaces with high heat loads. The cold plate 10 includes a first face panel 102, a second face panel 106 spaced apart from the first face panel 102, and a matrix of spheres 108, embedded in a polymer matrix 109, between the first and second face panels 102, 106. The first face panel 102 has an outer surface 101 facing away from the matrix of spheres 108 and an inner surface 103 adjacent to and facing towards the matrix of spheres 108. Similarly, the second face panel 106 has an outer surface 105 facing away from the matrix of spheres 108 and an inner surface 107 adjacent to and facing towards the matrix of spheres 108.

The first face panel 102 and the second face panel 106 can be made from any material suitable for fabrication and performance of a cold plate. Non-limiting examples of such panel materials include metals such as aluminum and copper, alloys thereof, ceramics (e.g., SiC), ceramic matrix composites, metal matrix composites, graphite-epoxy, and fiber composites, among others.

The outer surface 101 of the first face panel 102 is in thermal communication with a heat source 122. Non limiting examples of a heats source include one or more power electronic devices, one or more power electronic device assemblies that individually include one or more power electronic devices embedded in one or more printed circuit board (PCB) layers, and electromechanical devices such electric motors and rotors of electric motors, among others. In some variations, an optional heat spreader 124 is positioned between the outer surface 101 of the first face panel 102 and the heat source 122. In at least one variation, and when a heat spreader is not included, the heat source 122 is in direct contact with the outer surface 101 of the first face panel 102 (not shown). While in other variations, and when the heat spreader 124 is included, the heat spreader is in direct contact with the outer surface 101 of the first face panel 102 as illustrated in FIG. 1.

The second panel 106 has an outer (−z direction) surface 105 in thermal communication with a heat sink 150. In at least one variation, the heat sink 150 is in direct contact with the outer surface 105 of the second face panel 106.

In some variations, the matrix of spheres 108 extends completely between the inner surface 103 of the first face panel 102 and the inner surface 107 of the second face panel 106. And in such variations, the matrix of spheres 108 may or may not be in direct contact with and/or bonded to the inner surface 103 of the first face panel 102 and/or the inner surface 107 of the second face panel 106. In other variations, one or more layers of material (not shown) are disposed between the matrix of spheres 108 and the inner surface 103 of the first face panel 102 and/or the inner surface 107 of the second face panel 106. That is, at least a portion of the matrix of spheres 108 does not extend completely between the inner surface 103 of the first face panel 102 and the inner surface 107 of the second face panel 106.

The matrix of spheres 108 includes a plurality of high thermal conductivity (HTC) spheres 108m (also referred to herein as a “matrix of HTC spheres 108m”) and a plurality of low thermal conductivity (LTC) spheres 108c (also referred to herein as a “matrix of LTC spheres 108c”). The HTC spheres have a thermal conductivity greater than 100 W/m×K and the LTC spheres have a thermal conductivity of less than 10 W/m×K. For example, in some variations the HTC spheres 108m are made from a metal or alloy (e.g., copper or a copper alloy) with a thermal conductivity greater than 100 W/m×K or from a ceramic with a thermal conductivity greater than 100 W/m×K (e.g., silicon carbide (SiC)). In at least one variation, a subset of the HTC spheres 108m includes spheres are made from a metal or alloy with a thermal conductivity greater than 100 W/m×K and another subset of the HTC spheres 108m are made from a ceramic with a thermal conductivity greater than 100 W/m×K. And in at least one variation, the LTC spheres are made from a ceramic with a thermal conductivity of less than 10 W/m×K (SiO₂).

In some variations, the HTC spheres 108m and/or the LTC spheres 108c have an average diameter between about 1 millimeter (mm) and about 50 mm, e.g., between about 3 mm and about 25 mm. For example, in some variations, the HTC spheres 108m have an average diameter between about 3 mm and about 6 mm, between about 6 mm and about 9 mm, between about 9 mm and about 12 mm, between about 12 mm and about 15 mm, between about 15 mm and about 18 mm, between about 18 mm and about 21 mm, or between about 21 mm and about 25 mm. Similarly, in some variations, the LTC spheres 108c have an average diameter between about 3 mm and about 6 mm, between about 6 mm and about 9 mm, between about 9 mm and about 12 mm, between about 12 mm and about 15 mm, between about 15 mm and about 18 mm, between about 18 mm and about 21 mm, or between about 21 mm and about 25 mm.

In at least one variation, the HTC spheres 108m and the LTC spheres 108c are the same size, i.e., the average diameter of the HTC spheres 108m is generally equal (i.e., within 10%) to the average diameter of the LTC spheres 108c. In other variations, the HTC spheres 108m and the LTC spheres 108c are not the same size, i.e., the HTC spheres 108m and the LTC spheres 108c have average diameters that are not within 10% of each other. And in some variations, a subset of the HTC spheres 108m and the LTC spheres 108c are the same size, and another subset of the HTC spheres 108m and the LTC spheres 108c are not the same size.

The matrix of HTC spheres 108m define one or more heat conducting pathways 140 from the first face panel 102 to the second face panel 106, and the matrix of LTC spheres define one or more thermal insulated pathways (not labeled). That is, with the HTC spheres 108m (e.g., copper spheres) having a high thermal conductivity (e.g., greater than about 100 W/mK) and being in direct contact with each other, the vertical columns of HTC spheres 108m shown in FIG. 1 provide a path for enhanced heat transfer (i.e., a heat conducting pathway) from the first face panel 102 to the second face panel 104. And with the heat source 122 in thermal communication with the first face panel 102 and the heat sink 150 in thermal communication with the second face panel 106, the vertical columns of HTC spheres 108m provide heat conducting pathway(s) 140 for heat transfer from the heat source 122 to the heat sink 150. In contrast, and with the LTC spheres 108c having a low thermal conductivity (e.g., less than about 10 W/mK), the columns of LTC spheres 108c provide a reduced path(s) for heat transfer from the heat source 122 to the heat sink 150.

While FIG. 1, and other figures discussed below, illustrate alternating columns (z-direction) of HTC spheres 108m and LTC spheres 108c along the x-direction shown in the figures, it should be understood that the matrix of spheres 108 can include columns of HTC spheres 108m directly next to and in contact with each other and/or columns of LTC spheres 108c directly next to and in contact with each other. It should also be understood that by selecting the type of metal or alloy used to form the HTC spheres 108m, the type of ceramic used to form the LTC spheres 108c, the number of columns of HTC spheres 108m, and/or the number of columns of LTC spheres 108c, the rate of heat transfer from the heat source 122 to the heat sink 150 is desirably tuned or adjusted to a desired value or within a range of desired values. In addition, positioning or placement of the HTC spheres 108m and/or LTC spheres 108c in the columns shown in FIG. 1 can be facilitated with the use of a mesh ‘M’ or screen that partitions the space (volume) between the first face panel 102 and the second face panel 106 into columns for desired placement of the spheres 108.

Referring to FIG. 2, a side cross-sectional view of the cold plate 10 according to another form of the present disclosure is shown. The heat source 122 and the heat sink 150 are in thermal communication with the cold plate 10, however, and unlike the heat sink 150 illustrated in FIG. 1, the heat sink 150 in FIG. 1 does not extend the same length (x-direction) as the heat source 122, and the heat spreader 124 when included. In addition, the matrix of HTC spheres 108m include an upper (+z direction) row (x-direction) of HTC spheres 108m that provide for heat transfer towards vertical columns (z-direction) of HTC spheres 108m aligned vertically over the heat sink 150. In this manner, a heat conducting pathway(s) 141 from the portion(s) of the heat source 122 and/or heat spreader 124 extending beyond the heat sink 150 (i.e., not aligned vertically with the heat sink 150) is provided to the columns of HTC spheres 108m aligned vertically with the heats sink 150.

As noted above with respect to FIG. 1, the columns of HTC spheres 108m in FIG. 2 provide a heat conducting pathway(s) 140 for heat transfer to the heat sink 150. In addition, a thermal insulated region 145 is formed by the vertical columns of LTC spheres 108c extending between the upper (+z direction) row (x-direction) of HTC spheres 108m and the second face panel 106 such that one or more heat insulated regions 160 is formed or provided on the lower outer 105 of the second face panel 106. In this manner, heat is selectively routed and transferred from a heat source (e.g., heat source 122 and/or heat spreader 124) having a first surface area in contact with the first face panel 102 of the cold plate 10 to a heat sink having a second surface area, less than the first surface area, in contact with the second face panel 106 of the cold plate 100.

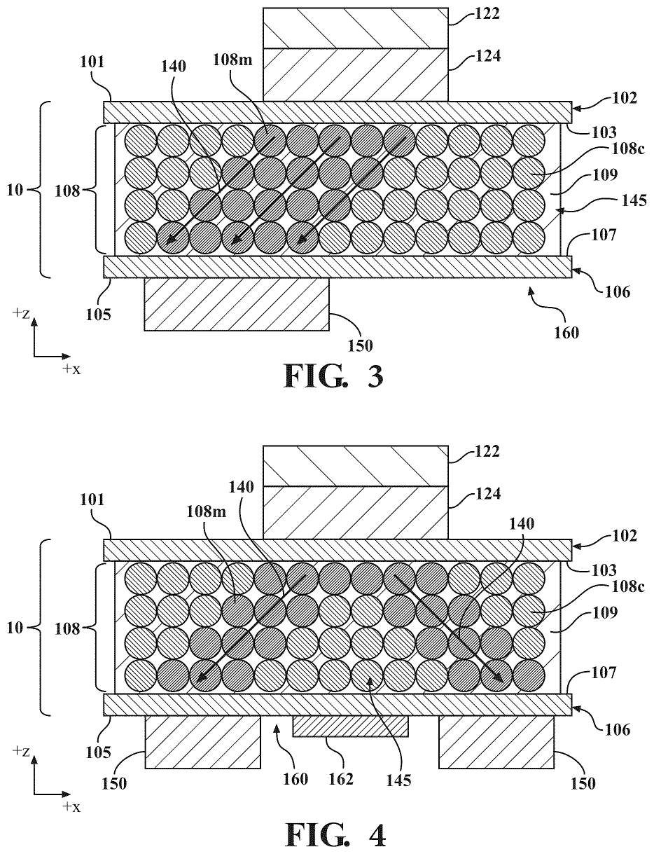

Referring to FIG. 3, a side cross-sectional view of the cold plate 10 according to still another form of the present disclosure is shown. The heat source 122 and the heat sink 150 are in thermal communication with the cold plate 10. However, and unlike the heat sink 150 illustrated in FIG. 1, the heat sink 150 in FIG. 3 is displaced relative to the heat source 122 and/or heat spreader 124 along the length direction (x-direction) of the cold plate 10. Also, the matrix of HTC spheres 108m includes diagonal columns (x-z direction) that provide for heat transfer from the heat source 122 and/or heat spreader 124 to the heat sink 150. In this manner, the diagonal columns of HTC spheres 108m provide a heat conducting pathway(s) 140 for heat transfer to a heat sink 150 that is not vertically aligned with a heat source 122 and/or heat spreader 124. Stated differently, the diagonal columns of HTC spheres 108m provide for selective routing and transfer of heat from a heat source 122 to a heat sink 150 that is not aligned with the heat source 122. In addition, a thermal insulated region 145 is formed by the diagonal and vertical columns of LTC spheres 108c extending between first face panel 102 and the second face panel 106 such that one or more heat insulated regions 160 is formed or provided on the outer surface 105 of the second face panel 106. And while FIG. 3 illustrates four (4) diagonal columns of HTC spheres 108m directly next to and in direct contact with each other, it should be understood that one or more of the diagonal columns of HTC spheres 108m can be a diagonal column of LTC spheres 108c.

Referring to FIG. 4, a side cross-sectional view of the cold plate 10 according to yet another form of the present disclosure is shown. The heat source 122 is in thermal communication with the cold plate 10, however, and unlike the heat sink 150 illustrated in FIG. 3, two heat sinks 150 spaced apart from each other and displaced relative to the heat source 122 and/or heat spreader 124 along the length direction (x-direction) of the cold plate 10 are included and are in thermal communication with the cold plate 10. Also, the matrix of spheres 108 includes two separate sets of diagonal columns (x-z direction) of HTC spheres 108m that provide for heat transfer from the heat source 122 and/or heat spreader 124 to the two heat sinks 150. In addition, a thermal insulated region 145 is formed by the LTC spheres 108c between two separate (spaced apart) sets of diagonal columns (x-z direction) of HTC spheres 108m such that a heat insulated region 160 is formed or provided on the outer surface 105 of the second face panel 106. In this manner, the two sets of diagonal columns of HTC spheres 108m provide a heat conducting pathway 140 for heat transfer to the two heat sinks 150 and heat is selectively routed and transferred from the heat source 122 and/or heat spreader 124 to multiple heat sinks 150. And while FIG. 4 illustrates three (3) diagonal columns of HTC spheres 108m directly next to and in direct contact with each other, it should be understood that the central diagonal column of HTC spheres 108m can be a diagonal column of LTC spheres 108c.

It should also be understood that selectively routing or transferring heat from the heat source 122 and/or heat spreader 124 to the two heat sinks 150 spaced apart from each other provides flexibility in the design and manufacture of electronic and/or electromechanical devices. For example, and as illustrated in FIG. 4, the heat insulated region 160 can be formed or be present on the second face panel 106 between the two spaced apart heat sinks 150. That is, selectively transferring heat along the diagonal columns of HTC spheres 108m, and having LTC spheres 108c extending between the diagonal columns of HTC spheres 108m, results in a significant reduction in heat transfer from the heat source 122 and/or heat spreader 124 to the heat insulated region 160. In some variations, the reduction in heat transfer from the heat source 122 and/or heat spreader 124 to the heat insulated region 160, compared to heat transfer from the heat source 122 and/or heat spreader 124 to each of the two heat sinks 150, is greater than 30%.

In some variations, and as illustrated in FIG. 4, a temperature sensitive electronic device 162 can be positioned and attached to the outer surface 105 of the second face panel 106. Non-limiting examples of the temperature sensitive electronic device 162 include optical components that require strict (narrow) temperature control.

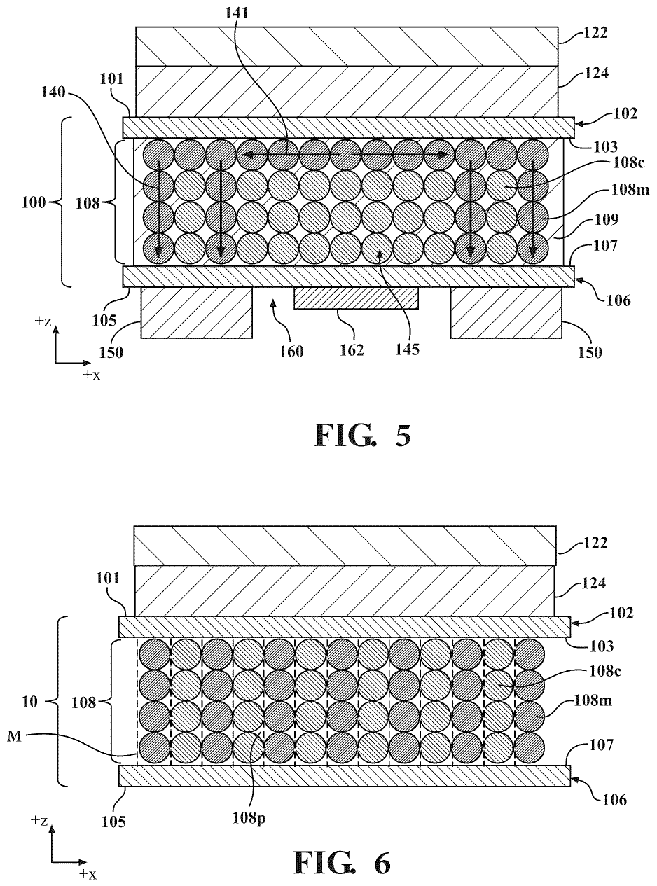

Referring to FIG. 5, a side cross-sectional view of the cold plate 10 according to still yet another form of the present disclosure is shown. The heat source 122, and optionally the heat spreader 124, and the two spaced apart heat sinks 150 are in thermal communication with the cold plate 10. However, and unlike the diagonal columns of HTC spheres 108m illustrated in FIG. 4, heat is transferred from the heat source 122 and/or the heat spreader 124 to the two spaced apart heats sinks 150 via vertical columns of HTC spheres 108m. Particularly, an upper (+z direction) horizontal row (x-direction) of HTC spheres 108m provides for enhanced heat transfer via the heat conducting pathways 141 to two separate sets of vertical columns of HTC spheres 108m vertically aligned with the heat sinks 150, which in turn provide heat conducting pathways 140 to the two heat sinks 150. In addition, a thermal insulated region 145 is formed by the LTC spheres 108c between the two separate sets of vertical columns of HTC spheres 108m such that a heat insulated region 160 is formed or provided on the outer surface 105 of the second face panel 106.

Similar to the matrix of spheres illustrated in FIG. 4, selectively routing or transferring heat from the heat source 122 and/or heat spreader 124 to the two heat sinks 150 spaced apart from each other as illustrated in FIG. 5, provides flexibility in the design and manufacture of electronic and/or electromechanical devices. For example, and as illustrated in FIG. 5, the heat insulated region 160 can be formed or present on the second face panel 106 between the two spaced apart heat sinks 150. That is, selectively transferring heat along the horizontal row and vertical columns of HTC spheres 108m, and having LTC spheres 108c extending between the vertical columns of HTC spheres 108m, results in a significant reduction in heat transfer from the heat source 122 and/or heat spreader 124 to the heat insulated region 160. In addition, in some variations a temperature sensitive electronic device 162 can be positioned and attached to the outer surface 105 of the second face panel 106 with the reduction in heat transfer from the heat source 122 and/or heat spreader 124 to the heat insulated region 160, compared to heat transfer from the heat source 122 and/or heat spreader 124 to each of the two heat sinks 150, being greater than 30%.

Referring now to FIG. 6, a cross-sectional view of the cold plate 10 according to another form of the present disclosure is shown. The heats source 122, and optionally the heat spreader 124, are in thermal communication with the cold plate 10. However, the matrix of spheres 108 is not embedded in a polymer matrix 109, and fluid passages (openings) 108p are present between the HTC spheres 108m and the LTC spheres 108c. Accordingly, fluid can flow through the matrix of spheres 108 via the fluid passages 108p such that heat transferred from the heat source 122 and/or heat spreader 124 to the cold plate 100 is removed by fluid flowing into, through, and out of the cold plate 10.

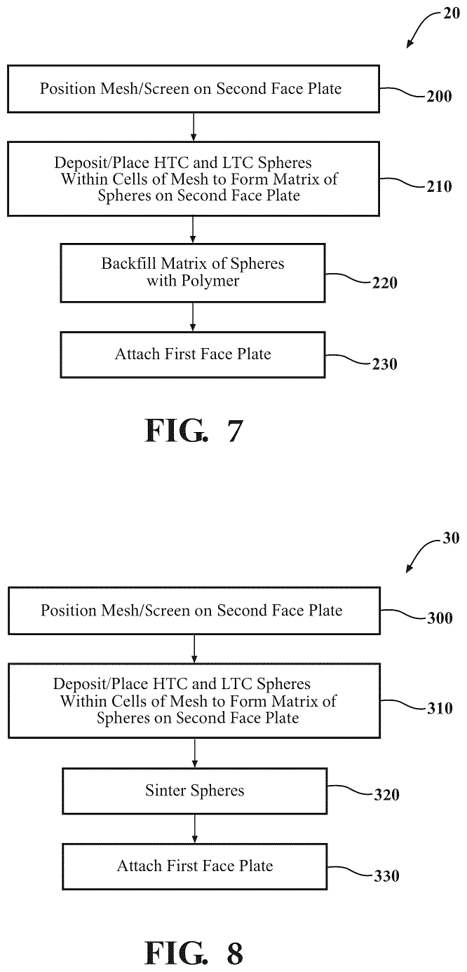

Referring now to FIG. 7, a flow chart for a method 20 of manufacturing the cold plates 10 discussed above with respect to FIGS. 1-5 is shown. The method 20 includes positioning a mesh M on the second face panel 106 at 200 such that the space/volume above (+z direction) the second face panel 106 is partitioned into cells. HTC spheres 108m and/or LTC spheres 108c are placed within cells of the mesh to form the matrix of spheres 108 on the second face panel at 210. The matrix of spheres 108 is backfilled with a polymer matrix 109 at 220 and the first face panel 102 is attached at 230 such that the cold plate 100 is formed. In some variations, the matrix of spheres is backfilled with the polymer matrix 109 by infiltration of a liquid polymer into the matrix of spheres 108, followed by solidification of the liquid polymer. In other variations, the matrix of spheres is backfilled with the polymer matrix 109 using a vapor deposition process.

Referring to FIG. 8, a flow chart for another method 30 of manufacturing the cold plates 10 discussed above with respect to FIG. 6 is shown. The method 30 includes positioning a mesh M on the second face panel 106 at 200 such that the space/volume above (+z direction) the second face panel 106 is partitioned into cells. HTC spheres 108m and/or LTC spheres 108c are placed within cells of the mesh to form the matrix of spheres 108 on the second face panel at 210. The matrix of spheres 108 is sintered at 320 and the first face panel 102 is attached at 240. It should be understood that the sintering process may lower the thermal conduction resistance by creating a continuous conduction heat transfer pathway (e.g., heat conducting pathway 140) through the thickness (z-direction) of the structure (including panels and spheres), thus further enhancing the heat flow control capability of the structure. Also, other sphere-to-sphere and sphere-to-plate bonding processes are included within the teachings of the present disclosure.

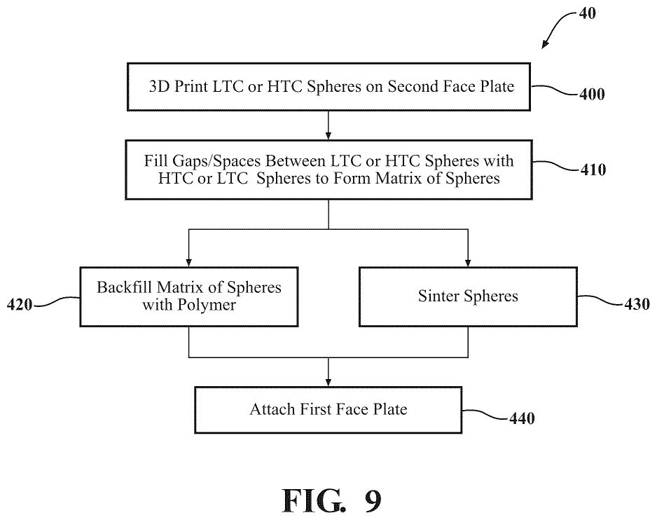

Referring to FIG. 9, a flow chart for still another method 40 of manufacturing the cold plates 10 discussed above with respect to FIGS. 1-6 is shown. The method 40 includes 3D printing a layer of LTC or HTC spheres 108c, 108m on the second face panel 106 at 400 and filling gaps/spaces between the LTC or HTC spheres 108c, 108m with HTC or LTC spheres 108m, 108c, respectively, at 410. In some variations, the gaps/spaces between the LTC or HTC spheres 108c, 108m are filled with HTC or LTC spheres 108m, 108c, respectively, layer-by-layer, i.e., after each layer of LTC or HTC spheres 108c, 108m is 3D printed, the gaps/spaces between the LTC or HTC spheres 108c, 108m are filled with HTC or LTC spheres 108m, 108c, respectively, until a matrix of spheres 108 is formed. In other variations, two or more layers of LTC or HTC spheres 108c, 108m are 3D printed before the gaps/spaces between the LTC or HTC spheres 108c, 108m are filled with HTC or LTC spheres 108m, 108c, respectively, until a matrix of spheres 108 is formed.

In at least one variation all of the HTC spheres 108m (e.g., SiC spheres) of a matrix of spheres 108 are 3D printed onto a second face panel 106 (e.g., a SiC face panel) such that one or more continuous high thermal conductivity pathways are formed, and then the spaces or cavities between the one or more continuous high thermal conductivity pathways (e.g., columns of SiC spheres) is back filled with LTC spheres 108c (e.g., glass spheres) to form the matrix of spheres 108. In another variation, all of the LTC spheres 108c (e.g., SiO₂ spheres) of a matrix of spheres 108 are 3D printed onto a second face panel 106 (e.g., a SiC face panel) such that one or more low thermal conductivity regions are formed, and then the spaces or cavities between the one or more continuous low thermal conductivity regions (e.g., columns of SiO₂ spheres) is back filled with HTC spheres 108m (e.g., SiC spheres) to form the matrix of spheres 108.

And after the matrix of spheres 108 is formed, in some variations the matrix of spheres 108 is backfilled with a polymer matrix 109 at 420, while in other variations the matrix of spheres 108 is sintered at 430. And in at least one variation the matrix of spheres 108 is sintered and then back filled with a polymer matrix 109. At 440, the first face panel 102 is attached such that the cold plate 10 is formed.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The figures illustrate the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range. The term “about” when used in relation to numerical numbers and/or numerical ranges refers to +/−10% of a numerical number and/or +/−10% of a numerical range to which the term “about” is associated with.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A cold plate for an electronic and/or electromechanical device, the cold plate comprising:
a first face panel and a second face panel spaced apart from the first face panel; and
a matrix of high thermal conductivity (HTC) spheres and a matrix of low thermal conductivity (LTC) spheres disposed between inner surfaces of the first and second face panels, the matrix of HTC spheres defining a heat conducting pathway between the first and second face panels, and the matrix of LTC spheres defining a thermal insulated region between the first and second face panels.

2. The cold plate according to claim 1, wherein the heat conducting pathway is a plurality of HTC spheres in direct contact with each other and extending between the first and second face panels.

3. The cold plate according to claim 1, wherein the thermal insulated region is a plurality of LTC spheres in direct contact with each other and extending between the first and second face panels.

4. The cold plate according to claim 1 further comprising a heat source in thermal communication with an outer surface of the first face panel, wherein the heat conducting pathway enhances heat transfer between the heat source and a heat sink on the second face panel and the thermal insulated region reduces heat transfer between the heat source and a heat insulated region on the second face panel.

5. The cold plate according to claim 4 further comprising a temperature sensitive electronic device in thermal communication with the heat insulated region on the second face panel.

6. The cold plate according to claim 5, wherein the temperature sensitive electronic device is attached to the heat insulated region on the second face panel.

7. The cold plate according to claim 4, wherein the heat conducting pathway comprises two heat conducting pathways between the heat source and two heat sinks spaced apart from each other on the second face panel.

8. The cold plate according to claim 7, wherein the two heat conducting pathways are defined by vertical columns extending between the heat source and the two heat sinks.

9. The cold plate according to claim 7, wherein the two heat conducting pathways are defined by diagonal columns extending between the heat source and the two heat sinks.

10. The cold plate according to claim 7, wherein the heat insulated region on the second face panel is between the two heat sinks.

11. The cold plate according to claim 1 further comprising a polymer matrix, the matrix of HTC spheres and the matrix of LTC spheres embedded within the polymer matrix.

12. The cold plate according to claim 1, wherein the matrix of HTC spheres is a sintered matrix of HTC spheres and fluid passages extend through the sintered matrix of HTC spheres.

13. The cold plate according to claim 1, wherein the matrix of LTC spheres is a sintered matrix of LTC spheres and fluid passages extend through the sintered matrix of LTC spheres.

14. The cold plate according to claim 1, wherein the matrix of HTC spheres is a sintered matrix of HTC spheres, the matrix of LTC spheres is a sintered matrix of LTC spheres, and fluid passages extend through the sintered matrix of HTC spheres and the sintered matrix of LTC spheres.

15. A cold plate for an electronic and/or electromechanical device, the cold plate comprising:
a first face panel and a second face panel spaced apart from the first face panel;
a matrix of HTC spheres and a matrix of LTC spheres disposed between inner surfaces of the first and second face panels, the matrix of HTC spheres defining a heat conducting pathway between the first and second face panels, and the matrix of LTC spheres defining a thermal insulated region between the first and second face panels;
a heat source in thermal communication with an outer surface of the first face panel; and
a heat sink in thermal communication with an outer surface of the second face panel, the heat conducting pathway enhancing heat transfer between the heat source and the heat sink, and the thermal insulated region reducing heat transfer between the heat source and a heat insulated region on the second face panel.

16. The cold plate according to claim 15, wherein the heat conducting pathway is a plurality of HTC spheres in direct contact with each other and extending between the first and second face panels.

17. The cold plate according to claim 15, wherein the thermal insulated region is a plurality of LTC spheres in direct contact with each other and extending between the first and second face panels.

18. The cold plate according to claim 15, wherein the matrix of HTC spheres and the matrix of LTC spheres are embedded in a polymer matrix.

19. A cold plate for an electronic and/or electromechanical device, the cold plate comprising:
a first face panel and a second face panel spaced apart from the first face panel;
a polymer matrix between inner surfaces of the first and second face panels;
a matrix of HTC spheres and a matrix of LTC spheres embedded in the polymer matrix, the matrix of HTC spheres defining a heat conducting pathway between the first and second face panels, and the matrix of LTC spheres defining a thermal insulated region between the first and second face panels;
a heat source in thermal communication with an outer surface of the first face panel; and
a heat sink in thermal communication with an outer surface of the second face panel, the heat conducting pathway enhancing heat transfer between the heat source and the heat sink, and the thermal insulated region reducing heat transfer between the heat source and a heat insulated region on the second face panel.

20. The cold plate according to claim 19, wherein the heat conducting pathway is a plurality of HTC spheres in direct contact with each other and extending between the first and second face panels, and the thermal insulated region is a plurality of LTC spheres in direct contact with each other and extending between the first and second face panels.
